(19) United States
(12) Patent Application Publication
(10) Pub. No.: US 2022/0084736 A1
(43) Pub. Date: Mar. 17, 2022

(54) TANDEM MAGNETICS IN PACKAGE

(71) Applicant: Intel Corporation, Santa Clara, CA (US)

(72) Inventors: Beomseok CHOI, Chandler, AZ (US); Adel A. ELSHERBINI, Chandler, AZ (US)

(21) Appl. No.: 17/020,200

(22) Filed: Sep. 14, 2020

(51) Int. Cl. H01F 27/28; H01F 38/14; H01F 17/00; H01F 27/24; H01F 27/40

(52) U.S. Cl. CPC H01F 27/2804; H01F 38/14; G06F 1/26; H01F 27/24; H01F 27/40; H01F 17/0033

(57) ABSTRACT

Embodiments disclosed herein include electronic packages and methods of forming such packages. In an embodiment, an electronic package comprises a package substrate and a first region in the package substrate. In an embodiment, the first region comprises first conductive routing. The electronic package may further comprise a second region in the package substrate. In an embodiment, the second region comprises second conductive routing. In an embodiment, the second conductive routing is embedded in a magnetic material.

### TECHNICAL FIELD

Embodiments of the present disclosure relate to semiconductor devices, and more particularly to electronic packages with embedded inductors surrounded by magnetic material.

### BACKGROUND

It is highly desired for power management integrated circuits (PMIC) and voltage regulators (VR) to have magnetic cored inductors packaged with the die in order to create a small form factor and a high-performance product. However, it is challenging to source or fabricate embedded or in-package high quality-factor (Q-factor) inductors while not sacrificing the overall solution footprint or design flexibility.

On-package discrete magnetic inductors are often used to package the magnetics with PMIC and VR. This option is used for cases where efficiency of the product is emphasized as a priority. However, such solutions suffer from an increase in the overall form factor. Additionally, the need to surface mount the discrete magnetic inductors can lead to assembly challenges. Package embedded magnetic inductors are used to keep the form factor minimal for PMIC or VR products. However, the choice of magnetic material and designs are limited. This usually results in significant performance penalties.

### BRIEF DESCRIPTION OF THE DRAWINGS

FIG. 1A is a plan view illustration of an electronic package with a magnetic region embedded in the package substrate, in accordance with an embodiment.

FIG. 1B is a plan view illustration of an electronic package with a magnetic region embedded in the package substrate, where the magnetic region is between a first die and a second die, in accordance with an embodiment.

FIG. 1C is a plan view illustration of an electronic package with a magnetic region embedded in the package substrate, where a second die is above the magnetic region, in accordance with an embodiment.

FIG. 2A is a cross-sectional illustration of an electronic package with an embedded magnetic region, in accordance with an embodiment.

FIG. 2B is a cross-sectional illustration of an electronic package with an embedded magnetic region that is at least partially below a die, in accordance with an embodiment.

FIG. 3 is a cross-sectional illustration of an electronic package with an embedded magnetic region that comprises an inductor, in accordance with an embodiment.

FIGS. 4A-4E are cross-sectional and plan view illustrations that depict a process for forming an embedded magnetic region with an inductor in the magnetic region, in accordance with an embodiment.

FIGS. 5A-5F are cross-sectional illustrations depicting a process for forming a magnetic region around a wire bond, in accordance with an embodiment.

FIG. 6 is a cross-sectional illustration of an electronic system with an embedded magnetic region in a package substrate, in accordance with an embodiment.

FIG. 7 is a schematic of a computing device built in accordance with an embodiment.

### EMBODIMENTS OF THE PRESENT DISCLOSURE

Described herein are electronic packages with embedded inductors surrounded by magnetic material, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, discrete magnetic components (e.g., discrete inductors surrounded by a magnetic material) result in form factor increases. Additionally, existing embedded inductors surrounded by magnetic materials are limited in design and material selection. As such, existing solutions for the components needed for power management integrate circuits (PMICs) and voltage regulators (VRs) are limited.

Accordingly, embodiment disclosed herein include embedded magnetic regions. The embedded magnetic regions may surround and contact conductive routing in the package substrate. Particularly, the conductive routing can be formed using standard package substrate manufacturing operations. After the conductive routing is formed, a cavity into the package substrate is formed, and the magnetic material is deposited to fill the cavity. Such assembly operations provide high flexibility in the design of the conductive routing that is embedded in the magnetic material. This allows freedom to choose inductance values (and other parameters) for the inductors.

Embodiments disclosed herein provide additional benefits as well. One such benefit is that high-Q magnetic inductors can be fabricated by using thick conductive layers. For example, lithographic vias can be used to stitch together neighboring traces in the package substrate to provide the thick conductive layers. Additionally, embodiments disclosed herein are fabricated during package substrate assembly, and do not require the attachment of discrete components. Form factor is also not impacted using embodiments described herein. For example, since the magnetic structures are embedded in the package substrate, there is no increase to the thickness of the package substrate.

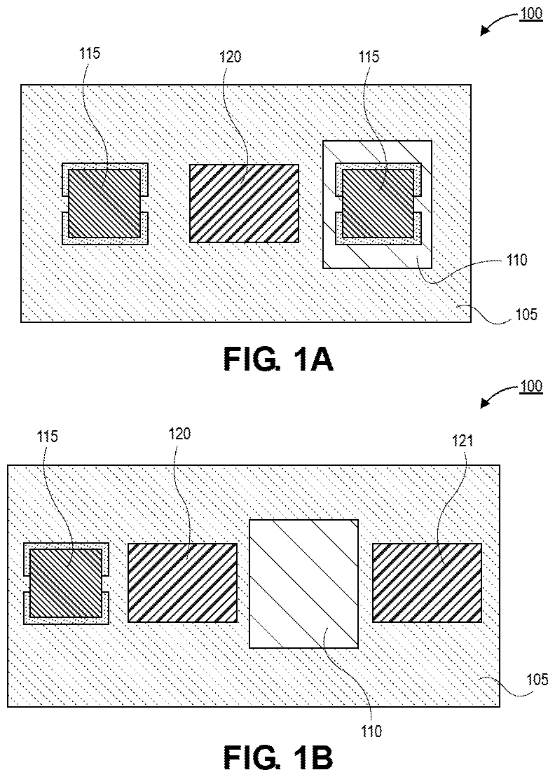

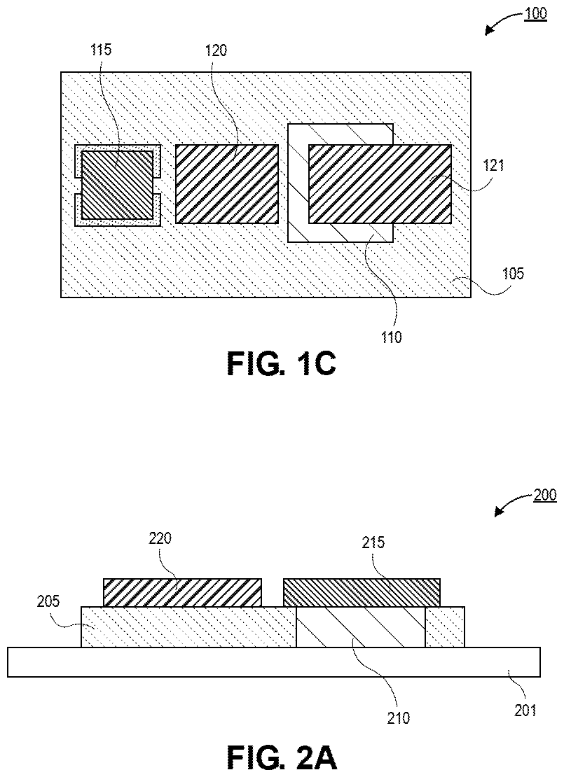

Referring now to FIG. 1A, a plan view illustration of an electronic package 100 is shown, in accordance with an embodiment. In an embodiment, the electronic package 100 comprises a package substrate 105. The package substrate 105 may be any suitable packaging substrate material. In the illustrated embodiment (and as described in greater detail herein) the package substrate 105 may be a molded package substrate. However, it is to be appreciated that the package substrate 105 is not limited to molded substrates. For example, the package substrate may include organic buildup layers, a ceramic substrate, or a glass substrate.

In an embodiment, a magnetic region 110 is embedded in the package substrate 105. As shown, a top surface of the magnetic region 110 is shown as being substantially coplanar with a top surface of the package substrate 105. In other embodiments, the magnetic region 110 may be fully embedded in the package substrate 105. That is, in some embodiments, the magnetic region 110 may not be visible from a top view of the electronic package 100.

In an embodiment, conductive features (not visible in FIG. 1A) may be provided in the magnetic region 110. For example, conductive traces, vias, etc. may be fully embedded by the magnetic region 110. The conductive features may function as passive devices. For example, the conductive features may comprise one or more loops to form an inductor or transformer that is embedded in the magnetic region 110.

In an embodiment, a discrete passive component 115 may be provided over a top surface of the magnetic region 110. The discrete passive component 115 may be a capacitor in some embodiments. As such, an LC circuit (sometimes called a tank circuit) can be provided to a die 120 when an inductor is formed in the magnetic region 110. In an embodiment, the die 120 may be a PMIC or a VR die.

Referring now to FIG. 1B, a plan view illustration of an electronic package 100 is shown, in accordance with an additional embodiment. In an embodiment, the electronic package 100 in FIG. 1B may be substantially similar to the electronic package in FIG. 1A, with the exception that the discrete passive is removed from above the magnetic region 110, and a second die 121 is provided over the package substrate 105. In an embodiment, the second die 121 may be a consumer of the first die (e.g., a PMIC or VR die). For example, the second die 121 may be an SoC, a processor, a graphics processor, or any other type of die.

Referring now to FIG. 1C, a plan view illustration of an electronic package 100 is shown, in accordance with an additional embodiment. In an embodiment, the electronic package 100 in FIG. 1C may be substantially similar to the electronic package 100 in FIG. 1B, with the exception that the second die 121 is disposed at least partially over a top surface of the magnetic region 110.

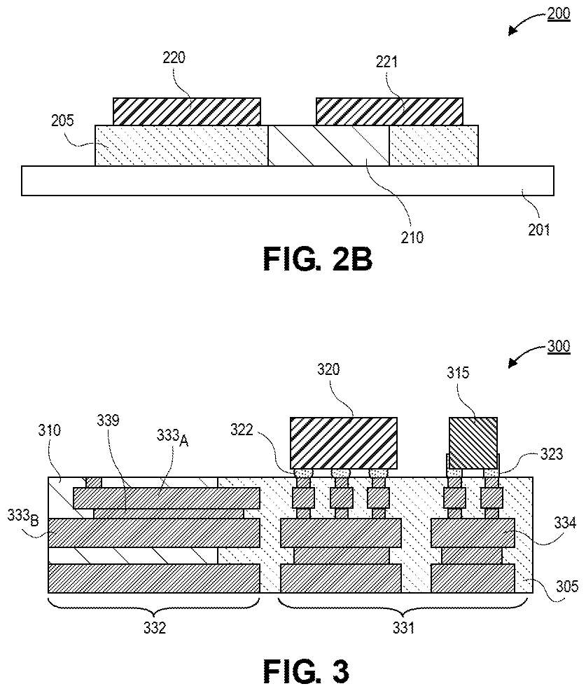

Referring now to FIG. 2A, a cross-sectional illustration of an electronic package 200 is shown, in accordance with an embodiment. In an embodiment, the electronic package 200 comprises a board 201 and a package substrate 205 connected to the board 201. The package substrate 205 may be connected to the board by any interconnect architecture, such as solder balls, sockets, or the like. In an embodiment, the board 201 may be a printed circuit board (PCB), a motherboard, or the like.

In an embodiment, the package substrate 205 may be any suitable package substrate material. For example, the package substrate 205 may be a molded package substrate, an organic package substrate, a ceramic package substrate, or a glass package substrate. In an embodiment, a magnetic region 210 may be embedded in the package substrate 205. As shown, the sidewalls of the magnetic region 210 are in direct contact with the package substrate 205. That is, there is not an intervening layer (such as a fill material) between the magnetic region 210 and the package substrate 205. Particularly, the magnetic region 210 is fabricated as part of the package substrate 205, and is not a discrete component that is embedded into the package substrate 205. The top and bottom surfaces of the magnetic region 210 may be substantially coplanar with the top and bottom surfaces of the package substrate 205. In other embodiments, one or both of the top and bottom surface of the magnetic region 210 may be covered by portions of the package substrate 205.

In the illustrated embodiment, conductive routing is omitted from the package substrate 205 and the magnetic region 210 for simplicity. However, it is to be appreciated that conductive routing is present in the package substrate 205 and the magnetic region 210, as will be described in greater detail below. For example, conductive routing in the magnetic region 210 may be used to form inductors and/or transformers that are surrounded by the magnetic material.

In an embodiment, the magnetic region 210 may comprise any material that can be disposed into a cavity. For example, the magnetic material may be a moldable compound in some embodiments. The magnetic material may comprise an epoxy with conductive fillers. The conductive fillers may include, but are not limited to, ferrites, iron alloys, and cobalt.

In an embodiment, a die 220 and a passive component 215 may be disposed over the package substrate 205 and the magnetic region 210. In an embodiment, the passive component 215 may comprise a capacitor, and the die 220 may comprise a PMIC or a VR die. When an inductor is provided in the magnetic region 210, a tank circuit (i.e., an LC circuit) can be provided to the die 220.

Referring now to FIG. 2B, a cross-sectional illustration of an electronic package 200 is shown, in accordance with an additional embodiment. In an embodiment, the electronic package 200 in FIG. 2B is substantially similar to the electronic package 200 in FIG. 2A, with the exception that a second die 221 replaces the passive 215. In an embodiment, the first die 220 may be a PMIC or VR, and the second die 221 may be the consumer of power from the first die 220. As shown, the second die 221 may be over a portion of the magnetic region 210. The allowed overlap enables real estate space savings.

Referring now to FIG. 3, a cross-sectional illustration of an electronic package 300 is shown, in accordance with an embodiment. The electronic package 300 includes a package substrate 305. The package substrate 305 may be a molded substrate, an organic substrate, a ceramic substrate, or a glass substrate. In an embodiment, the package substrate 305 may comprise a first region 331 and a second region 332. The first region 331 may comprise base routing. That is, the first region 331 may comprise conductive features 334 that are suitable for providing electrical routing in order to provide electrical connections to components attached to the package substrate.

In an embodiment, the components may include a die 320 and a passive 315. The die 320 may be coupled to the package substrate by solder balls 322 or any other suitable interconnect. The passive 315 may be connected by solder 323. In an embodiment, the die 320 may be a PMIC or a VR die. The passive 315 may be a discrete capacitor or the like. In an embodiment, the die 320 and the passive 315 are provided over the first region 331 of the package substrate 305. However, it is to be appreciated that one or more dies 320 and/or passives 315 may be provided over the second region 332 of the package substrate.

In an embodiment, the second region 332 may comprise a magnetic region 310. The magnetic region 310 may be substantially embedded by the package substrate 305. For example, sidewalls of the magnetic region 310 may be in direct contact with the package substrate 305. However, in some embodiments, the magnetic region 310 may be at the edge of the package substrate 305, as shown in FIG. 3. In such an embodiment, a sidewall surface of the magnetic region 310 may be exposed. In other embodiments, all of the sidewalls of the magnetic region 310 are directly contacted by the package substrate 305.

In the illustrated embodiment, the magnetic region 310 has a thickness that is equal to a thickness of the package substrate 305. That is, the magnetic region 310 may pass through a plurality of routing layers of the package substrate 305. In other embodiments, the magnetic region 310 may extend through fewer than all of the routing layers of the package substrate 305. For example, one or more routing layers within the package substrate 305 may be provided above and/or below the magnetic region 310.

In an embodiment, the magnetic region 310 may comprise a magnetic material that is a moldable compound. The magnetic material may comprise an epoxy that is filled with magnetic particles. For example, the magnetic particles may include, but are not limited to, ferrites, iron alloys, and cobalt.

In an embodiment, conductive routing 333 may be provided in the second region 332. Portions of the conductive routing 333 in the second region 332 may be in direct contact with the magnetic material of the magnetic region 310. For example, portions of the traces of conductive routing 333 have a first end in the magnetic region and a second end in the package substrate 305. Additionally, it is to be appreciated that the conductive routing that is embedded in both the magnetic region 310 and the package substrate 305 is a continuous trace. That is, there is no discernable interface along the conductive routing at the interface between the magnetic region 310 and the package substrate 305. In other embodiments, an entire trace may be embedded in the magnetic region 310.

In an embodiment, the conductive routing 333 may comprise electrical features suitable for the formation of passive components. For example, conductive routing 333 may include one or more conductive loops in order to form inductors and/or transformers. In some embodiments, the thickness of the conductive routing 333 is increased through the use of lithographically defined vias 339. For example, via 339 is a line via that couples together conductive routing 333A and 333B. As such, the feature (e.g., loop) formed by the via 339 and conductive routing 333A and 333B has a reduced resistance and a higher Q-factor is provided to the passive device. While lithographically fabricated vias are shown, it is to be appreciated that other via formation techniques may be used to provide interconnects between layers of the conductive routing 333.

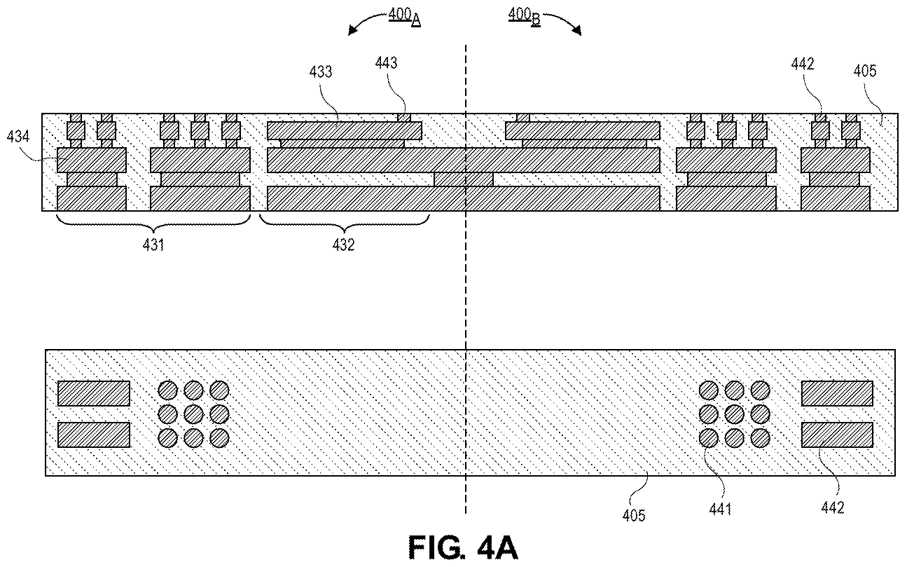

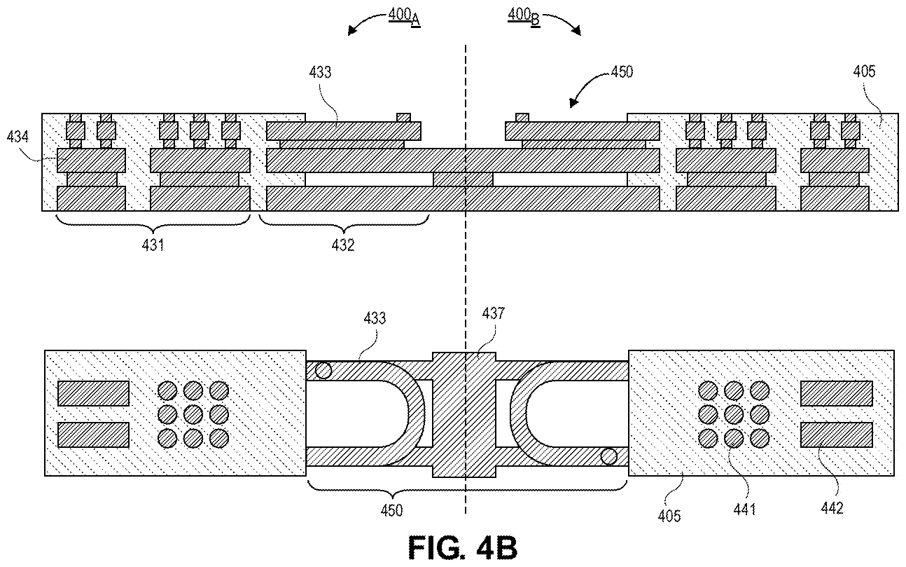

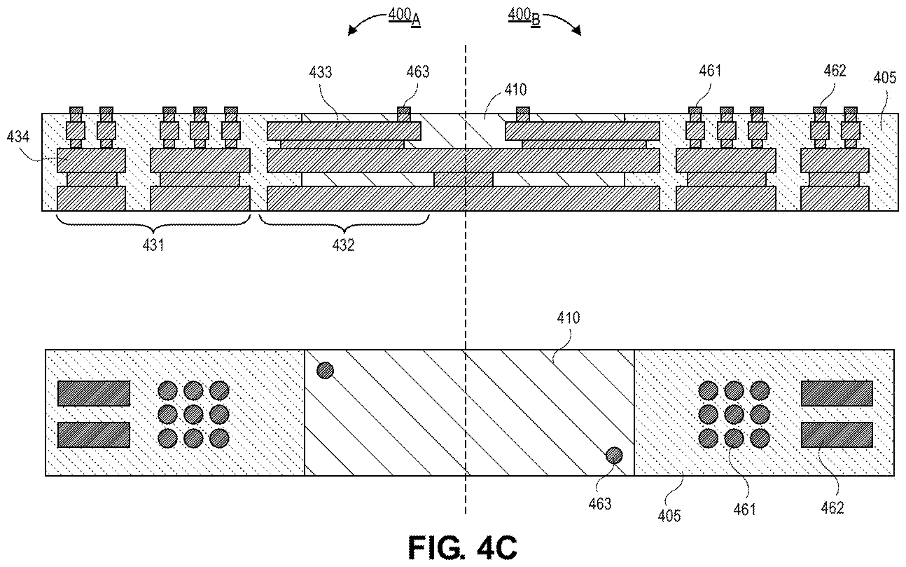

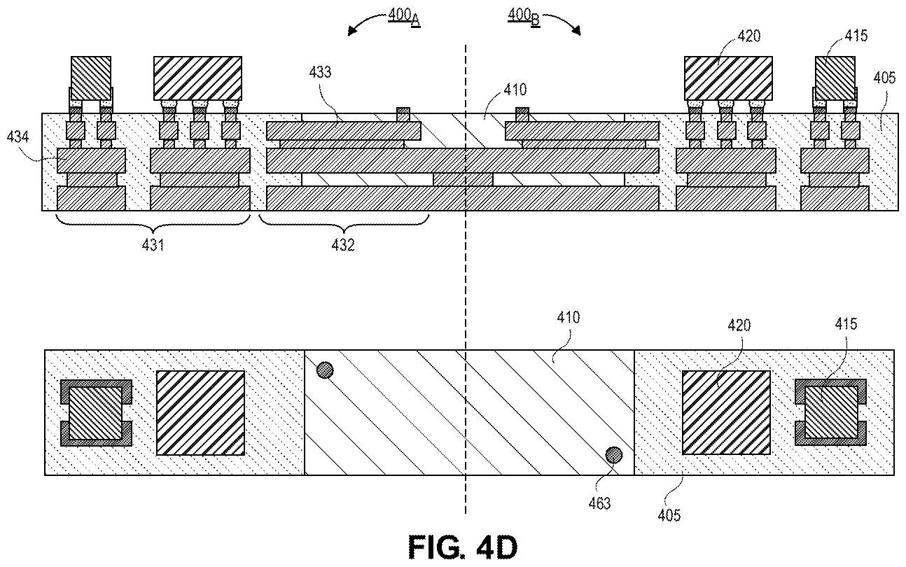

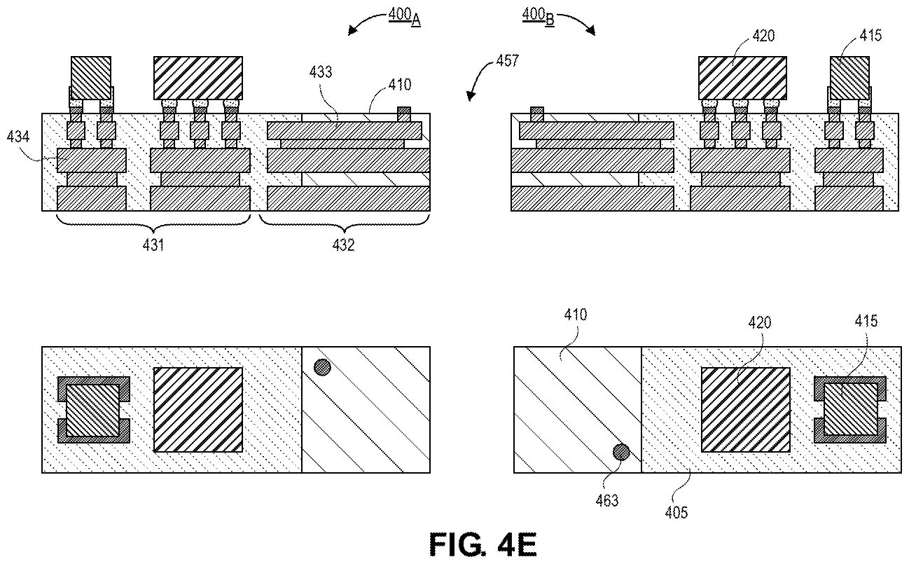

Referring now to FIGS. 4A-4E, a series of cross-sectional illustrations and corresponding plan view illustrations depicting a process for forming an electronic package is shown, in accordance with an embodiment. In the illustrated embodiment, a strip level fabrication process is shown. However, it is to be appreciated that embodiments may also allow for fabrication at the quarter panel level or panel level. In the illustrated embodiment, a first electronic package 400A is fabricated along the left side of the figures, and a second electronic package 400B is fabricated along the right side of the figures. In an embodiment, the first electronic package 400A and the second electronic package 400B may be substantially similar to each other.

Referring now to FIG. 4A, a cross-sectional illustration (top) and a plan view illustration (bottom) of electronic packages 400A and 400B are shown, in accordance with an embodiment. In an embodiment, electronic packages 400A and 400B are linked together in a single package substrate 405. The package substrate 405 may include a molded substrate, an organic substrate, a ceramic substrate, or a glass substrate.

In an embodiment, all layers of the electronic packages 400A and 400B are fabricated at this point. That is, all of the conductive routing 434 and 433 are provided within the package substrate 405. However, in other embodiments, processes to form the magnetic region may be implemented before completion of all of the routing layers. In an embodiment, the electronic packages 400 include a first region 431 and a second region 432. The first region 431 includes routing for providing interconnections between devices and/or routing from a die to a solder bump on the bottom of the electronic packages 400. The routing in the first region 431 may sometimes be referred to as the base routing. Vias 441 and 442 may also be provided over the first region 431 for connecting passives and/or dies in a subsequent processing operation. The second region 432 includes routing 433 for providing passive components. For example, the routing 433 may include one or more conductive loops in order to form inductors and/or transformers in the electronic packages 400. One or more vias 443 may be provided over the routing 433 in the second region 432.

Referring now to FIG. 4B, a cross-sectional illustration (top) and a plan view illustration (bottom) of the electronic packages 400A and 400B after a cavity 450 is formed through the package substrate 405 is shown, in accordance with an embodiment. In an embodiment, the cavity 450 may be formed with an etching process, a laser ablation process, or any other suitable process. In an embodiment, the cavity 450 removes portions of the package substrate 405 around conductive routing 433 in the second region 432. For example, the cavity 450 may extend through an entire thickness of the package substrate 405. However, in other embodiments, portions of the package substrate 405 may remain when the cavity 450 has a depth less than the thickness of the package substrate 405.

Removal of the package substrate 405 may also result in changes to the surface of the conductive routing 433. For example, evidence of etching or burning may be exhibited as an increase in surface roughness of the conductive routing 433 compared to the surface roughness of the conductive routing 434 that remains surrounded by the package substrate 405.

In an embodiment, a linking region 437 may provide structural support to keep the first electronic package 400A mechanically coupled to the second electronic package 400B. That is, formation of the cavity 450 may not result in the complete singulation of the structure. Furthermore, while the embodiments shown herein have the cavity 450 formed along edges of the electronic packages 400A and 400B, the cavity 450 may also be formed away from the edges of the electronic packages 400A and 400B. In such an embodiment, a separate cavity 450 may be formed for each of the electronic packages 400A and 400B.

In an embodiment, the exposed conductive routing 433 may be further processed after the formation of the cavity 450. For example, the additive manufacturing processes (e.g., cold spray) may be used to increase the thicknesses of the conductive routing 433. Additionally, embodiments may include providing a conductive surface finish or a dielectric over the conductive routing 433. The presence of a conductive surface finish or dielectric may improve the adhesion to the subsequently deposited magnetic material. A dielectric may also provide electrical isolation between the conductive routing 433 and the subsequently deposited magnetic material.

As shown in FIG. 4B, some portions of the conductive routing 433 may extend beyond the edge of the cavity 450. In such instances, the conductive routing 433 may have a first end that is further processed as described above, and a second end that remains substantially similar to the conductive routing 434 in the first region 431. However, it is to be appreciated that despite differences in the surface of the opposing ends of the conductive routing 433, the conductive routing may have substantially no seam at the interface of the package substrate 405 and the cavity 450.

Referring now to FIG. 4C, a cross-sectional illustration (top) and a plan view illustration (bottom) of the electronic packages 400A and 400B after the deposition of the magnetic region 410 is shown, in accordance with an embodiment. In an embodiment, the magnetic region 410 comprises a magnetic material that is moldable. For example, the magnetic material may comprise epoxy with magnetic fillers, such as, but not limited to ferrites, iron alloys, and cobalt. As shown, the magnetic region 410 may be in direct contact with portions of the package substrate 405. That is there is no intervening layer (e.g., a fill layer) between surfaces of the magnetic region 410 and surfaces of the package substrate 405. The magnetic region 410 may also directly contact portions of the conductive routing 433. However, surface finishes or a dielectric may also separate the conductive routing 433 from the magnetic material of the magnetic region 410 in some embodiments. The magnetic material of the magnetic region 410 may be planarized with a top surface of the package substrate 405. In an embodiment, pads and/or surface finishes 463, 461, and 462 may also be plated over the exposed surfaces of the conductive routing 434 in the first region 431 and the conductive routing 433 in the second region 432.

Referring now to FIG. 4D, a cross-sectional illustration (top) and a plan view illustration (bottom) of the electronic packages 400A and 400B after components are attached is shown, in accordance with an embodiment. In an embodiment, a die 420 is attached to both of the electronic packages 400A and 400B. The die 420 may be a PMIC or a VR die. In an embodiment, one or more discrete passives 415 may be coupled to the electronic packages 400A and 400B as well. For example, the discrete passives 415 may comprise capacitors or the like. While not illustrated in FIG. 4D, one or more components may also be provided over the magnetic region 410. As such, real estate savings may be provided in some embodiments.

Referring now to FIG. 4E, a cross-sectional illustration and a plan view illustration of the electronic packages 400A and 400B after singulation is shown, in accordance with an embodiment. The singulation may be implemented through the linking region 437 between the two packages 400A and 400B to form trench 457. The singulation may be any suitable singulation process such as mechanical sawing, laser ablation, or the like.

In FIGS. 4A-4E, the processing flow included forming a cavity through the entire thickness of the package substrate 405. However, it is to be appreciated that the magnetic region 410 need not pass through the entire thickness of the package substrate 405. Additionally, the magnetic region 410 may surround features other than the conductive routing 433 of the second region 432. For example, the magnetic region 410 may surround a wire bond.

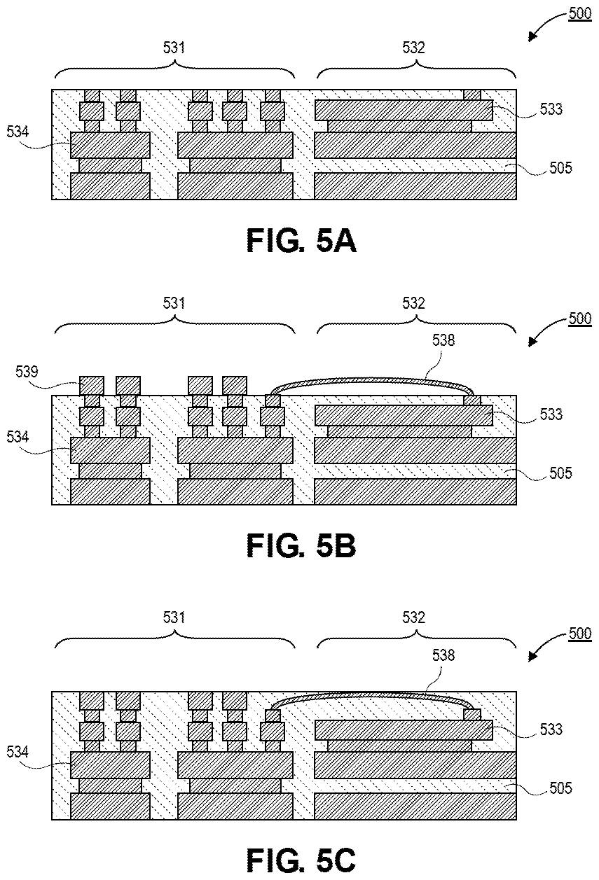

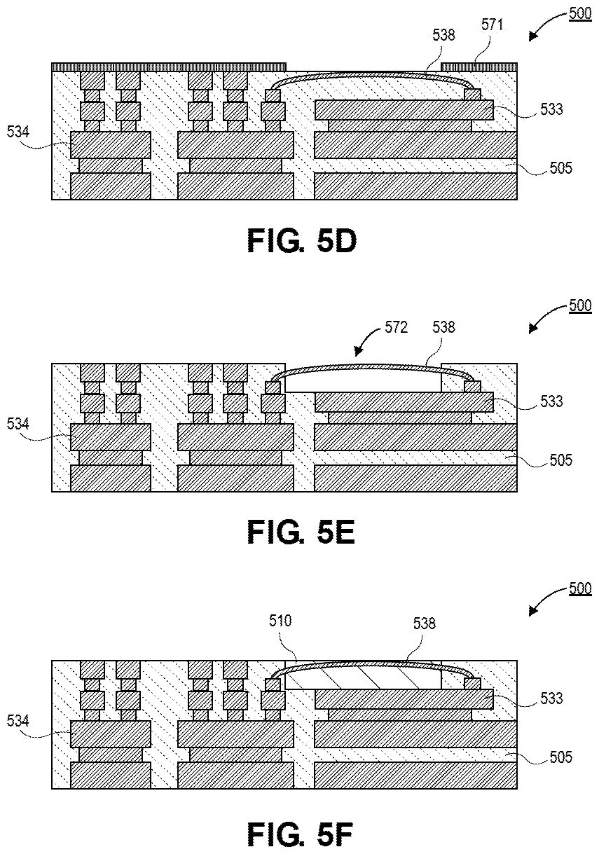

An example of a process for forming the magnetic region around a wire bond is shown in FIGS. 5A-5F. In FIGS. 5A-5F, a single electronic package 500 is shown. However, it is to be appreciated that the electronic package 500 may be fabricated at the strip level, quarter panel level, or panel level, similar to the embodiment shown in FIGS. 4A-4E.

Referring now to FIG. 5A, a cross-sectional illustration of an electronic package 500 is shown, in accordance with an embodiment. In an embodiment, the electronic package 500 comprises a package substrate 505. In an embodiment, the package substrate 505 may comprise a molded substrate, an organic substrate, a ceramic substrate, or a glass substrate. The package substrate 505 may have a first region 531 and a second region 532. The first region 531 may include base conductive routing 534, and the second region 532 may comprise conductive routing 533 for use in the embedded passive devices. For example, the second region 532 may include one or more conductive loops to form an inductor and/or a transformer.

Referring now to FIG. 5B, a cross-sectional illustration of the electronic package 500 after a wire bond 538 connecting the conductive routing 533 in the second region 532 to the conductive routing 534 in the first region 531 is shown, in accordance with an embodiment. The wire bond 538 may extend up above a top surface of the package substrate 505. In an embodiment, additional conductive vias 539 are also provided over the conductive routing 534 in the first region 531.

Referring now to FIG. 5C, a cross-sectional illustration of the electronic package 500 after the package substrate 505 is extended to cover the wire bond 538 is shown, in accordance with an embodiment. In an embodiment, the additional portion of the package substrate 505 may be formed with a suitable process, such as lamination, molding or the like.

Referring now to FIG. 5D, a cross-sectional illustration of the electronic package 500 after a mask layer 571 is disposed over the top surface of the package substrate 505 is shown, in accordance with an embodiment. In an embodiment, the mask layer 571 may be a material that is etch resistant to an etchant used to etch away portions of the package substrate 505. The mask layer 571 may have an opening over the wire bond 538.

Referring now to FIG. 5E, a cross-sectional illustration of the electronic package 500 after a cavity 572 is formed into the package substrate 505 is shown, in accordance with an embodiment. The cavity 572 may be made with an etching process in some embodiments. The cavity 572 exposes portions (or all of) the wire bond 538. For example, the cavity 572 in FIG. 5E exposes a central portion of the wire bond 538, while a first end and a second end of the wire bond 538 remains covered by the package substrate 505. In an embodiment, the cavity 572 may not extend entirely through the package substrate 505. For example, the cavity 572 is formed to a depth down to the top surface of the uppermost routing layer 533.

Referring now to FIG. 5F, a cross-sectional illustration of the electronic package 500 after a magnetic region 510 is disposed in the cavity 572 is shown, in accordance with an embodiment. In an embodiment, the magnetic region 510 comprises a magnetic material that is moldable. For example, the magnetic material may comprise an epoxy that include magnetic filler particles, such as, but not limited to, ferrites, iron alloys, and cobalt. After the magnetic region 510 is formed, excess magnetic material above the cavity 572 may be removed with a planarization process. Subsequent processing operations may then be implemented to attach components, singulate the electronic package 500, or the like, as is common in the semiconductor packaging field.

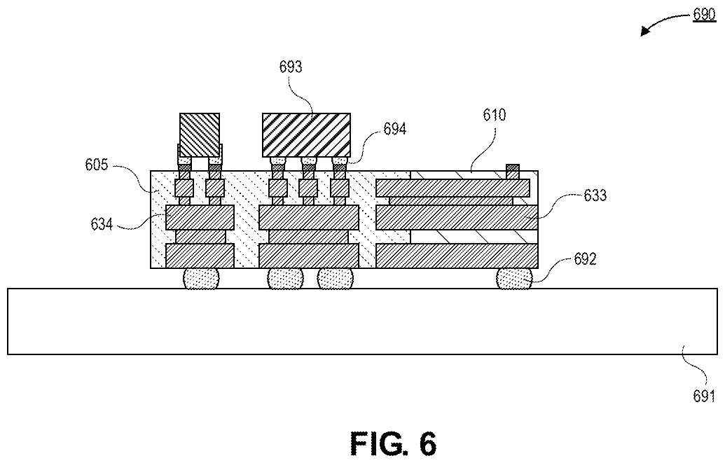

Referring now to FIG. 6, a cross-sectional illustration of an electronic system 690 is shown, in accordance with an embodiment. The electronic system 690 may comprise a board 691, such as a PCB or motherboard. A package substrate 605 is coupled to the board 691 by interconnects 692. The interconnects 692 may include solder balls, sockets, or the like. In an embodiment, one or more dies 693 are coupled to the package substrate 605 by interconnects 694. The interconnects 694 may be solder balls or any other first level interconnect (FLI) architecture.

In an embodiment, the package substrate 605 may comprise a first region with conductive routing 634 that is embedded in the package substrate 605, and a second region that comprises a magnetic region 610. Conductive routing 633 may be provided in the magnetic region 610 to provide high-Q inductors or transformers. In an embodiment, the package substrate 605 may be substantially similar to any of the package substrates with embedded magnetic regions described above.

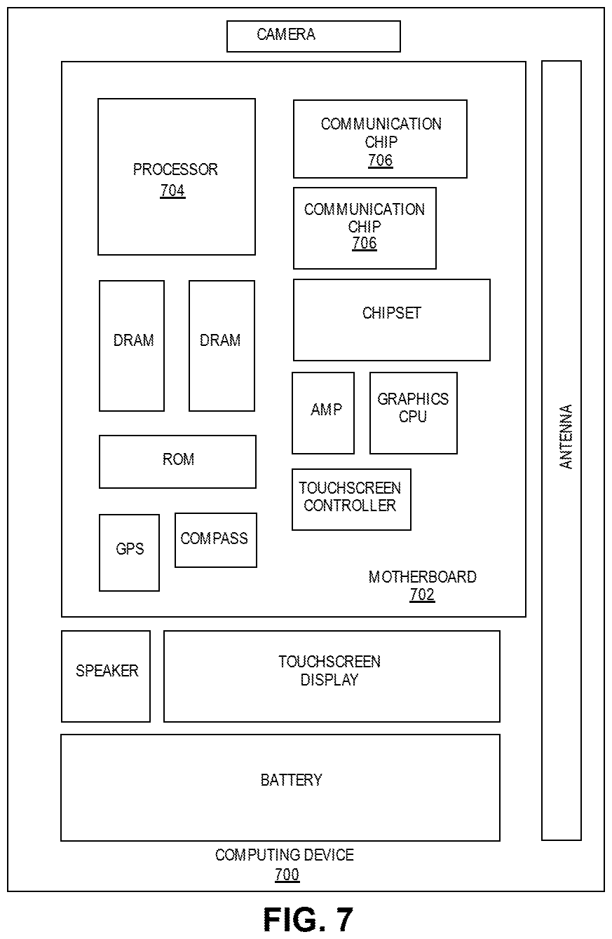

FIG. 7 illustrates a computing device 700 in accordance with one implementation of the invention. The computing device 700 houses a board 702. The board 702 may include a number of components, including but not limited to a processor 704 and at least one communication chip 706. The processor 704 is physically and electrically coupled to the board 702. In some implementations the at least one communication chip 706 is also physically and electrically coupled to the board 702. In further implementations, the communication chip 706 is part of the processor 704.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 706 enables wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 706 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 700 may include a plurality of communication chips 706. For instance, a first communication chip 706 may be dedicated to shorter range wireless communications such as Wi-Fi and Bluetooth and a second communication chip 706 may be dedicated to longer range wireless communications such as GPS, EDGE, GPRS, CDMA, WiMAX, LTE, Ev-DO, and others.

The processor 704 of the computing device 700 includes an integrated circuit die packaged within the processor 704. In some implementations of the invention, the integrated circuit die of the processor may be coupled to an electronic package that comprises an embedded magnetic region around one or more conductive loops to form a high-Q inductor and/or transformer, in accordance with embodiments described herein. The term “processor” may refer to any device or portion of a device that processes electronic data from registers and/or memory to transform that electronic data into other electronic data that may be stored in registers and/or memory.

The communication chip 706 also includes an integrated circuit die packaged within the communication chip 706. In accordance with another implementation of the invention, the integrated circuit die of the communication chip may be coupled to an electronic package that comprises an embedded magnetic region around one or more conductive loops to form a high-Q inductor and/or transformer, in accordance with embodiments described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

### Example 1

an electronic package, comprising: a package substrate; a first region in the package substrate, wherein the first region comprises first conductive routing; and a second region in the package substrate, wherein the second region comprises second conductive routing, and wherein the second conductive routing is embedded in a magnetic material.

### Example 2

the electronic package of Example 1, wherein the package substrate comprises a plurality of layers, and wherein the magnetic material is disposed through more than one of the plurality of layers.

### Example 3

the electronic package of Example 2, wherein the magnetic material is disposed through all of the plurality of layers.

### Example 4

the electronic package of Examples 1-3, wherein the second conductive routing comprises a conductive loop.

### Example 5

the electronic package of Example 4, wherein the conductive loop directly contacts the magnetic material.

### Example 6

the electronic package of Example 4, wherein the conductive loop forms an inductor.

### Example 7

the electronic package of Examples 1-6, wherein the second conductive routing comprises a wire bond.

### Example 8

the electronic package of Examples 1-7, wherein a surface roughness of the second conductive routing is greater than a surface roughness of the first conductive routing.

### Example 9

the electronic package of Examples 1-8, wherein the second conductive routing comprises a first end embedded in the magnetic material and a second end embedded in the package substrate, and wherein the first end and the second end are coupled together with a seamless interface.

### Example 10

the electronic package of Examples 1-9, wherein the second conductive routing is proximate to an edge of the package substrate.

### Example 11

the electronic package of Examples 1-10, wherein the package substrate is a molded substrate, an organic substrate, a ceramic substrate, or a glass substrate.

### Example 12

an electronic system, comprising: a die; a package substrate, wherein the die is attached to a surface of the package substrate, wherein the package substrate comprises a cavity, and wherein the cavity is filled with a magnetic material; and conductive routing through the magnetic material in the cavity.

### Example 13

the electronic system of Example 12, wherein the conductive routing forms an inductor.

### Example 14

the electronic system of Example 12 or Example 13, further comprising: a discrete passive device over the magnetic material.

### Example 15

the electronic system of Example 14, wherein the discrete passive device is a capacitor and the conductive routing forms an inductor, and wherein the capacitor and the inductor are electrically coupled to the die as an LC tank circuit.

### Example 16

the electronic system of Examples 12-15, further comprising: a second die attached to the surface of the package substrate, wherein the second die is positioned over the magnetic material.

### Example 17

the electronic system of Examples 12-16, wherein the die is a power management integrated circuit (PMIC) or a voltage regulator (VR).

### Example 18

a method of forming an electronic package, comprising: disposing first conductive routing and second conductive routing in a package substrate, wherein the second conductive routing is adjacent to the first conductive routing; removing a portion of the package substrate over and around the second conductive routing; and disposing a magnetic material around the second conductive routing.

### Example 19

the method of Example 18, further comprising: singulating the package substrate to form a first electronic package and a second electronic package.

### Example 20

the method of Example 19, wherein the singulation line is through the magnetic material over and around the second conductive routing.

### Example 21

the method of Examples 18-20, wherein removing the portion of the package substrate comprises a laser ablation process or an etching process.

### Example 22

the method of Examples 18-21, wherein the second conductive routing comprises a loop to form an inductor.

### Example 23

the method of Examples 18-22, wherein removing the portion of the package substrate comprises forming a cavity completely through the package substrate.

### Example 24

an electronic system, comprising: a board; an electronic package electrically coupled to the board, wherein the electronic package comprises: a package substrate with a cavity, and wherein the cavity is filled with a magnetic material; and conductive routing through the magnetic material in the cavity, wherein the conductive routing directly contacts the magnetic material; and a die electrically coupled to the electronic package.

### Example 25

the electronic system of Example 24, wherein the conductive routing forms an inductor.

What is claimed is:

1. An electronic package, comprising:
a package substrate;
a first region in the package substrate, wherein the first region comprises first conductive routing; and
a second region in the package substrate, wherein the second region comprises second conductive routing, and wherein the second conductive routing is embedded in a magnetic material.

2. The electronic package of claim 1, wherein the package substrate comprises a plurality of layers, and wherein the magnetic material is disposed through more than one of the plurality of layers.

3. The electronic package of claim 2, wherein the magnetic material is disposed through all of the plurality of layers.

4. The electronic package of claim 1, wherein the second conductive routing comprises a conductive loop.

5. The electronic package of claim 4, wherein the conductive loop directly contacts the magnetic material.

6. The electronic package of claim 4, wherein the conductive loop forms an inductor.

7. The electronic package of claim 1, wherein the second conductive routing comprises a wire bond.

8. The electronic package of claim 1, wherein a surface roughness of the second conductive routing is greater than a surface roughness of the first conductive routing.

9. The electronic package of claim 1, wherein the second conductive routing comprises a first end embedded in the magnetic material and a second end embedded in the package substrate, and wherein the first end and the second end are coupled together with a seamless interface.

10. The electronic package of claim 1, wherein the second conductive routing is proximate to an edge of the package substrate.

11. The electronic package of claim 1, wherein the package substrate is a molded substrate, an organic substrate, a ceramic substrate, or a glass substrate.

12. An electronic system, comprising:
a die;
a package substrate, wherein the die is attached to a surface of the package substrate, wherein the package substrate comprises a cavity, and wherein the cavity is filled with a magnetic material; and
conductive routing through the magnetic material in the cavity.

13. The electronic system of claim 12, wherein the conductive routing forms an inductor.

14. The electronic system of claim 12, further comprising:
a discrete passive device over the magnetic material.

15. The electronic system of claim 14, wherein the discrete passive device is a capacitor and the conductive routing forms an inductor, and wherein the capacitor and the inductor are electrically coupled to the die as an LC tank circuit.

16. The electronic system of claim 12, further comprising:
a second die attached to the surface of the package substrate, wherein the second die is positioned over the magnetic material.

17. The electronic system of claim 12, wherein the die is a power management integrated circuit (PMIC) or a voltage regulator (VR).

18. A method of forming an electronic package, comprising:
disposing first conductive routing and second conductive routing in a package substrate, wherein the second conductive routing is adjacent to the first conductive routing;
removing a portion of the package substrate over and around the second conductive routing; and
disposing a magnetic material around the second conductive routing.

19. The method of claim 18, further comprising:
singulating the package substrate to form a first electronic package and a second electronic package.

20. The method of claim 19, wherein the singulation line is through the magnetic material over and around the second conductive routing.

21. The method of claim 18, wherein removing the portion of the package substrate comprises a laser ablation process or an etching process.

22. The method of claim 18, wherein the second conductive routing comprises a loop to form an inductor.

23. The method of claim 18, wherein removing the portion of the package substrate comprises forming a cavity completely through the package substrate.

24. An electronic system, comprising:
a board;
an electronic package electrically coupled to the board, wherein the electronic package comprises:
a package substrate with a cavity, and wherein the cavity is filled with a magnetic material; and
conductive routing through the magnetic material in the cavity, wherein the conductive routing directly contacts the magnetic material; and
a die electrically coupled to the electronic package.

25. The electronic system of claim 24, wherein the conductive routing forms an inductor.
